(19) United States
(12) Patent Application Publication
(10) Pub. No.: US 2015/0162169 A1
(43) Pub. Date: Jun. 11, 2015

(54) ETCHING APPARATUS AND METHOD

(71) Applicant: TAIWAN SEMICONDUCTOR MANUFACTURING CO., LTD., HSINCHU (TW)

(72) Inventor: Shih-Hung CHEN, Hsinchu County (TW)

(73) Assignee: TAIWAN SEMICONDUCTOR MANUFACTURING CO., LTD., HSINCHU (TW)

(21) Appl. No.: 14/098,416

(22) Filed: Dec. 5, 2013

(51) Int. Cl. H01J 37/32

(52) U.S. Cl. CPC H01J 37/32449; H01J 37/32724; H01J 37/32697; H01J 37/32321; H01J 2237/3341

(57) ABSTRACT

An apparatus is disclosed for etching a wafer or substrate. The apparatus includes a process reaction chamber, a gas distribution plate, and an electrostatic chuck. The gas distribution plate is disposed in the process reaction chamber, and is used for entrance of a main processing gas. The electrostatic chuck is disposed in the process reaction chamber and has an adsorption surface. The wafer or substrate is disposed on the adsorption surface. The electrostatic chuck further has a plurality of first gas inlets for entrance of a plurality of auxiliary processing gases. Each of the first gas inlets is communicated with the adsorption surface and aligned with at least a part of a circumference of the wafer or substrate. The gas distribution plate and the electrostatic chuck are located at two opposite sides of the process reaction chamber, respectively.

### FIELD

The present disclosure relates to an etching apparatus and method for etching a wafer or substrate.

### BACKGROUND

A semiconductor wafer is processed in a semiconductor manufacturer to form various integrated circuits (IC) in different regions of the wafer. The integrated circuit formed on the semiconductor substrate includes a plurality of semiconductor devices. Various semiconductor manufacturing processes are employed to form the semiconductor devices, including etching, lithography, ion implantation, thin film deposition, and thermal annealing.

During the manufacturing of semiconductor devices, unwanted layers (or particles) are often deposited on wafers from known or unknown sources. Such deposition may occur on various layers of a wafer, such as the substrate, photoresist layer, photo mask layer, and/or other layers of the wafer. Currently, manufacturers use some semiconductor tools (such as a shower head) to inject the process gases into the reaction chamber, so as to remove undesirable layers from wafers. Some semiconductor tools have multi-zone design of the gas injection to improve center-edge etching or deposition amount and its uniformity.

### BRIEF DESCRIPTION OF THE DRAWINGS

The disclosure can be more fully understood by reading the following detailed description of various embodiments, with reference to the accompanying drawings as follows:

FIG. 1 is a schematic diagram of an etching apparatus for etching a wafer or substrate in accordance with some further embodiments of the present disclosure;

FIG. 2 is a sectional view of an electrostatic chuck along line 2-2′ in FIG. 1;

FIG. 3 is a partial schematic diagram of the etching apparatus in FIG. 1 in accordance with some other embodiments of the present disclosure;

FIG. 4 is a partial schematic diagram of the etching apparatus in FIG. 1 in accordance with some other embodiments of the present disclosure;

FIG. 5 is a schematic diagram of an etching apparatus for etching a wafer or substrate in accordance with some other embodiments of the present disclosure;

FIG. 6 is a schematic diagram of an etching apparatus for etching a wafer or substrate in accordance with some embodiments of the present disclosure;

FIG. 7 is a sectional view of an electrostatic chuck along line 7-7′ in FIG. 6;

FIG. 8 is a partial schematic diagram of the etching apparatus in FIG. 6 in accordance with some other embodiments of the present disclosure;

FIG. 9 is a partial schematic diagram of the etching apparatus in FIG. 6 in accordance with some embodiments of the present disclosure;

FIG. 10 is a schematic diagram of an etching apparatus for etching a wafer or substrate in accordance with some other embodiments of the present disclosure; and

FIG. 11 is a flow chart of a etching method for etching a wafer or substrate in accordance with some embodiments of the present disclosure.

### DETAILED DESCRIPTION

In the following description, specific details are presented to provide a thorough understanding of the embodiments of the present disclosure. Persons of ordinary skill in the art will recognize, however, that the present disclosure can be practiced without one or more of the specific details, or in combination with other components. Well-known implementations or operations are not shown or described in detail to avoid obscuring aspects of various embodiments of the present disclosure.

The terms used in this specification generally have their ordinary meanings in the art and in the specific context where each term is used. The use of examples in this specification, including examples of any terms discussed herein, is illustrative only, and in no way limits the scope and meaning of the disclosure or of any exemplified term. Likewise, the present disclosure is not limited to various embodiments given in this specification.

It will be understood that, although the terms “first,” “second,” etc., may be used herein to describe various elements, these elements should not be limited by these terms. These terms are used to distinguish one element from another. For example, a first element could be termed a second element, and, similarly, a second element could be termed a first element, without departing from the scope of the embodiments. As used herein, the term “and/or” includes any and all combinations of one or more of the associated listed items.

As used herein, the terms “comprising,” “including,” “having,” “containing,” “involving,” and the like are to be understood to be open-ended, i.e., to mean including but not limited to.

Reference throughout the specification to “one embodiment” or “an embodiment” means that a particular feature, structure, implementation, or characteristic described in connection with the embodiment is included in at least one embodiment of the present disclosure. Thus, uses of the phrases “in one embodiment” or “in an embodiment” in various places throughout the specification are not necessarily all referring to the same embodiment. Furthermore, the particular features, structures, implementation, or characteristics may be combined in any suitable manner in one or more embodiments.

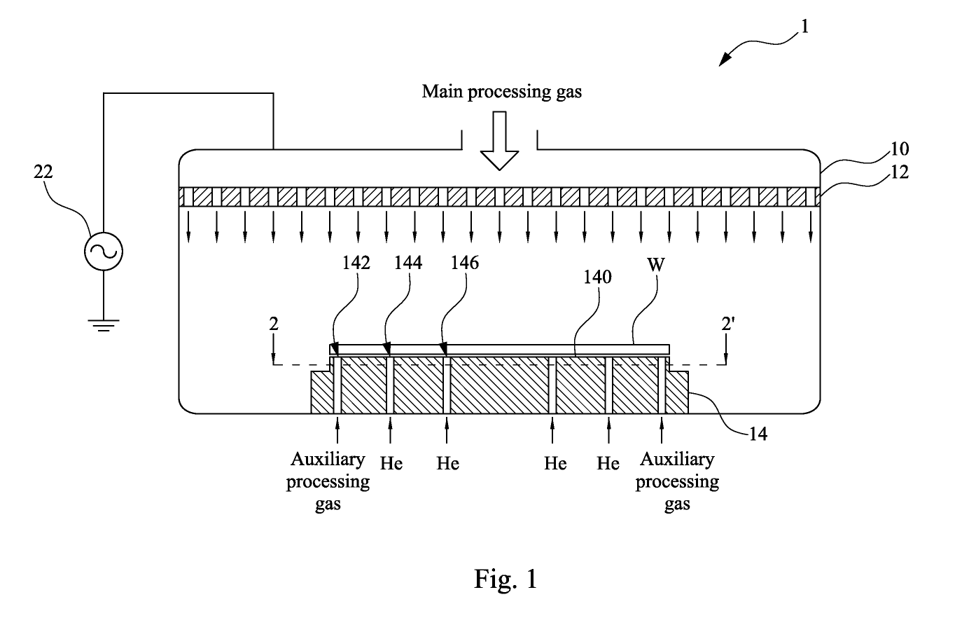

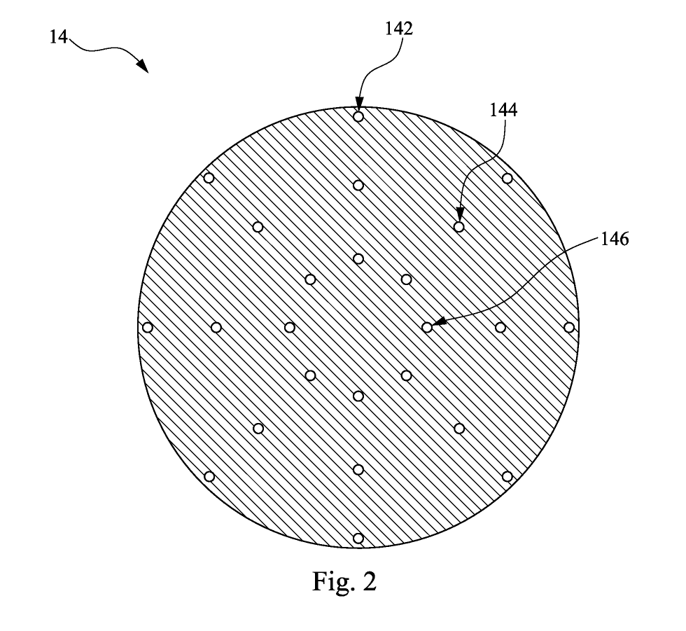

FIG. 1 is a schematic diagram of an etching apparatus 1 for etching a wafer or substrate W in accordance with some further embodiments of the present disclosure. FIG. 2 is a sectional view of an electrostatic chuck 14 along line 2-2′ in FIG. 1.

As shown in FIG. 1, the etching apparatus 1 includes the process reaction chamber 10, the gas distribution plate 12, and the electrostatic chuck 14. The gas distribution plate is located in the process reaction chamber 10, and is for entrance of a main processing gas. A gas source (not shown) supplies the main processing gas to be ionized, to the process reaction chamber 10 via the gas distribution plate 12. The main processing gas flowing from the gas distribution plate 12 is excited by an electric field generating device 22 to generate a plasma. The electrostatic chuck 14 is located in the process reaction chamber 10 and has an adsorption surface 140 for supporting and securing a wafer or substrate W to be etched. That is, the wafer or substrate W is located on the adsorption surface 140 of the electrostatic chuck 14. The electrostatic chuck 14 holds the wafer or substrate W to be etched using the ions in the plasma.

As shown in FIG. 1 and FIG. 2, the electrostatic chuck 14 further has a plurality of first gas inlets 142 for entrance of auxiliary processing gases. Each of the first gas inlets 142 is communicated with the adsorption surface 140 and aligned with at least a part of the edge of the wafer or substrate W. The gas distribution plate 12 and the electrostatic chuck 14 are located at two opposite sides of the process reaction chamber 10, respectively. The second processing gas exhausted out from the first gas inlets 142 is excited by the electric field generating device 22 to generate another plasma.

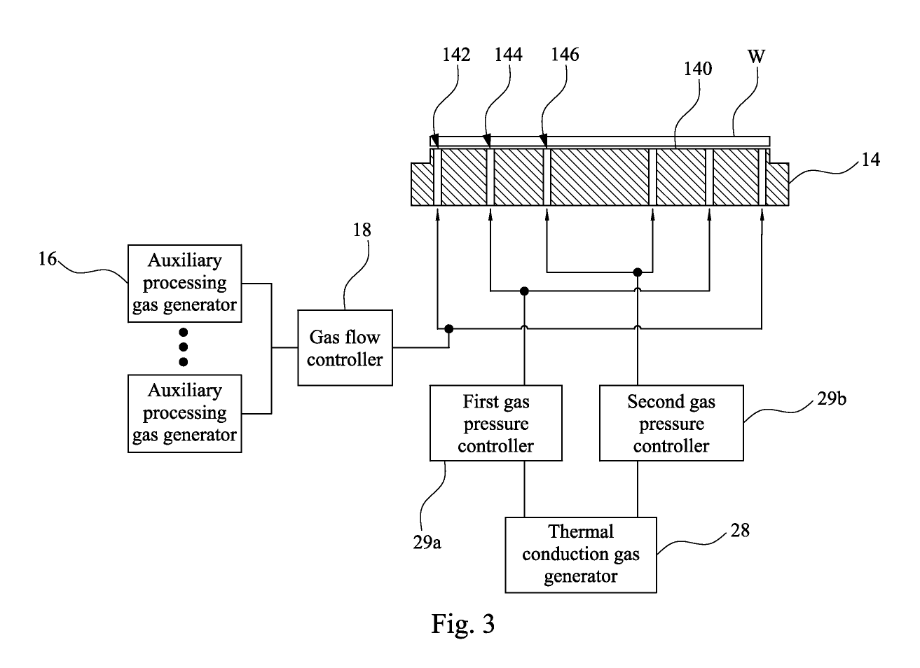

FIG. 3 is a partial schematic diagram of the etching apparatus 1 in FIG. 1 in accordance with some other embodiments of the present disclosure.

As shown in FIG. 3, the etching apparatus 1 further includes a plurality of auxiliary processing gas generators 16 and a gas flow controller 18. The auxiliary processing gas generators 16 are communicated with the first gas inlets, and respectively generate the auxiliary processing gases. The gas flow controller 18 is communicated with the auxiliary processing gas generators 16 and the first gas inlets 142. The gas flow controller 18 is capable of selectively allowing one of the auxiliary processing gases to exhaust out of the first gas inlets 142.

For example, if a photo resist layer deposited at the bevel of the wafer or substrate W needs to be removed, the gas flow controller 18 can allow the auxiliary processing gas generator 16 that generates oxygen to exhaust out of the first gas inlets 142. If an oxide layer deposited at the bevel of the wafer or substrate W needs to be removed, the gas flow controller 18 can allow the auxiliary processing gas generator 16 that generates fluorine-based gas to exhaust out of the first gas inlets 142.

The number of the auxiliary processing gas generators 16 in FIG. 3 is given for illustrative purposes. Other numbers and configurations of the auxiliary processing gas generators 16 are within the contemplated scope of the present disclosure.

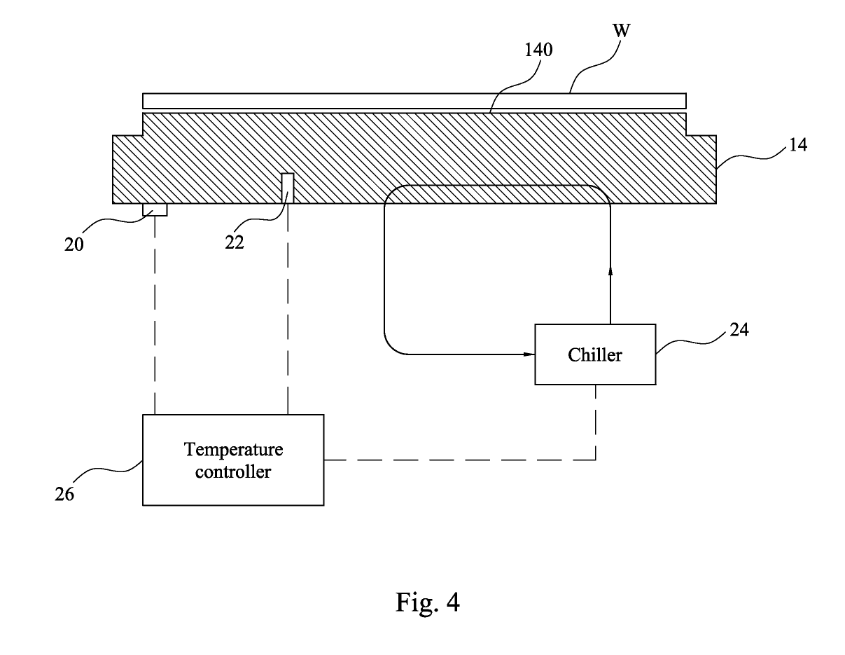

FIG. 4 is a partial schematic diagram of the etching apparatus 1 in FIG. 1 in accordance with some other embodiments of the present disclosure.

As shown in FIG. 4, the etching apparatus 1 further includes a temperature sensor 20, a heater 22, a chiller 24, and a temperature controller 26. The temperature sensor 20 is thermally connected to the electrostatic chuck 14. The temperature sensor 20 is capable of detecting an actual temperature of the electrostatic chuck 14. The heater 22 and the chiller 24 are thermally connected to the electrostatic chuck 14. The temperature controller 26 is electrically connected to the temperature sensor 20, the heater 22, and the chiller 24. The temperature controller 26 is capable of driving the heater 22 and the chiller 24 to adjust the actual temperature of the electrostatic chuck 14 to a predetermined temperature.

As shown in FIG. 3, the electrostatic chuck 14 further has a plurality of second gas inlets 144 for entrance of a thermal conduction gas. The distance between any of the second gas inlets 144 and the center of the adsorption surface 140 is smaller than the distance between any of the first gas inlets 142 and the center of the adsorption surface 140. Hence, the thermal conduction gas exhausted out from the second gas inlets 144 of the electrostatic chuck 14 can flow within the gap between the backside (i.e., the lower side) of the wafer or substrate W and the adsorption surface 140 of the electrostatic chuck 14. Thus, the electrostatic chuck 14 can adjust the wafer or substrate W to the predetermined temperature by the thermal conduction gas exhausted out from the second gas inlets 144 of the electrostatic chuck 14 in the form of thermal convection.

The electrostatic chuck 14 further has a plurality of third gas inlets 146 for entrance of the thermal conduction gas. The distance between any of the third gas inlets 146 and the center of the adsorption surface 140 is smaller than the distance between any of the second gas inlets 144 and the center of the adsorption surface 140. Similarly, the thermal conduction gas exhausted out from the third gas inlets 146 of the electrostatic chuck 14 can also flow within the gap between the backside of the wafer or substrate W and the adsorption surface 140 of the electrostatic chuck 14.

Furthermore, as shown in FIG. 3, the etching apparatus 1 further includes a thermal conduction gas generator 28, a first gas pressure controller 29a, and a second gas pressure controller 29b. The thermal conduction gas generator 28 is communicated with the second gas inlets 144 and the third gas inlets 146. The thermal conduction gas generator 28 is capable of generating the thermal conduction gas. The first gas pressure controller 29a is communicated with the thermal conduction gas generator 28 and the second gas inlets 144. The first gas pressure controller 29a is capable of adjusting the thermal conduction gas exhausted out from the second gas inlets 144 to a first air pressure. The second gas pressure controller 29b is communicated with the thermal conduction gas generator 28 and the third gas inlets 146. The second gas pressure controller 29b is capable of adjusting the thermal conduction gas exhausted out from the third gas inlets 146 to a second air pressure different from the first air pressure. Hence, the first air pressure of the thermal conduction gas exhausted out from the second gas inlets 144 can be selectively adjusted to be larger than or smaller than the second air pressure of the thermal conduction gas exhausted out from the third gas inlets 146 as needed, so that the process flexibility of the etching apparatus 1 of the present application can be increased.

The numbers of the first gas inlets 142, the second gas inlets 144, and the third gas inlets 146 in FIG. 2 are given for illustrative purposes. Other numbers and configurations of the first gas inlets 142, the second gas inlets 144, and the third gas inlets 146 are within the contemplated scope of the present disclosure.

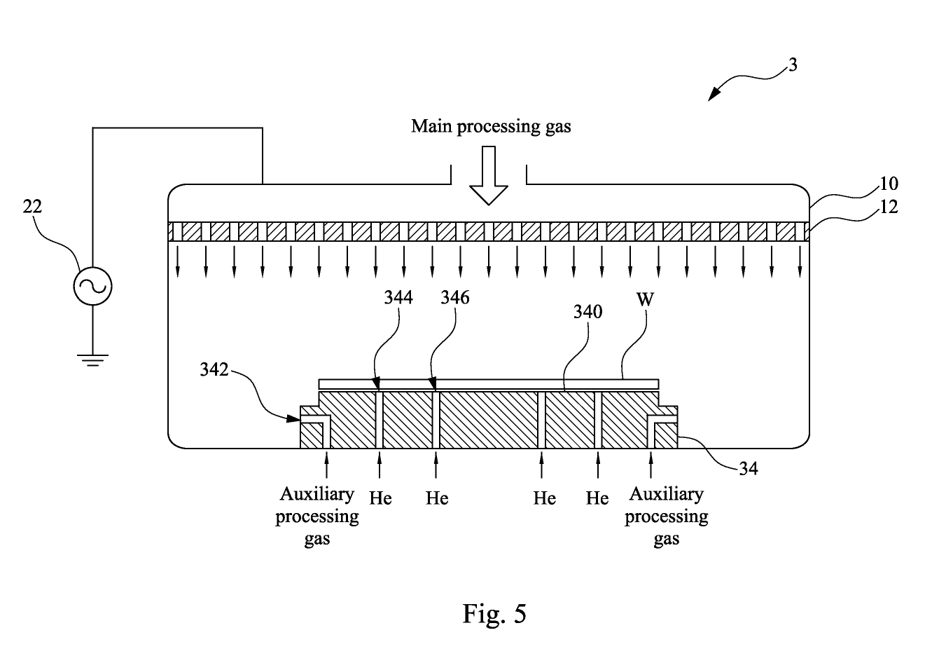

FIG. 5 is a schematic diagram of an etching apparatus 3 for etching a wafer or substrate W in accordance with some other embodiments of the present disclosure.

As shown in FIG. 5, the etching apparatus 5 includes a process reaction chamber 10, a gas distribution plate 12, and the electrostatic chuck 34. The structures and functions of the process reaction chamber 10 and the gas distribution plate 12 can be referred to the related descriptions of FIG. 1 to FIG. 4. The electrostatic chuck 34 is located in the process reaction chamber 10 and has an adsorption surface 340 for supporting and securing a wafer or substrate W to be etched. The electrostatic chuck 34 further has a plurality of first gas inlets 342 for entrance of auxiliary processing gases. It should be pointed out that compared with the embodiment in FIG. 1, each of the first gas inlets 342 is communicated with the sidewall of the electrostatic chuck 34 and adjacent to the edge of the wafer or substrate W, rather than communicated with the adsorption surface 340. That is, the first gas inlets 342 do not aligned with the edge of the wafer or substrate W. However, because the first gas inlets 342 communicated with the sidewall of the electrostatic chuck 34 are still adjacent to the edge of the wafer or substrate W, the auxiliary processing gases exhausted out from the first gas inlets 342 can also achieve the purpose of fine tuning the behavior of the etching amount of the edge of the wafer or substrate W, or removing the polymer at the bevel of the wafer or substrate W.

The electrostatic chuck 34 further has a plurality of second gas inlets 344 and a plurality of third gas inlets 346. The second gas inlets 344 are for entrance of a thermal conduction gas. The third gas inlets 346 are for entrance of the thermal conduction gas. The distance between any of the second gas inlets 344 and the center of the adsorption surface 340 is smaller than the distance between any of the first gas inlets 342 and the center of the adsorption surface 340. Hence, the thermal conduction gas exhausted out from the second gas inlets 344 of the electrostatic chuck 34 can flow within the gap between the backside (i.e., the lower side) of the wafer or substrate W and the adsorption surface 340 of the electrostatic chuck 34. Thus, the electrostatic chuck 34 can adjust the wafer or substrate W to the predetermined temperature by the thermal conduction gas exhausted out from the second gas inlets 344 of the electrostatic chuck 34 in the form of thermal convection. The distance between any of the third gas inlets 346 and the center of the adsorption surface 340 is smaller than the distance between any of the second gas inlets 344 and the center of the adsorption surface 340. Similarly, the thermal conduction gas exhausted out from the third gas inlets 346 of the electrostatic chuck 34 can also flow within the gap between the backside of the wafer or substrate W and the adsorption surface 340 of the electrostatic chuck 34.

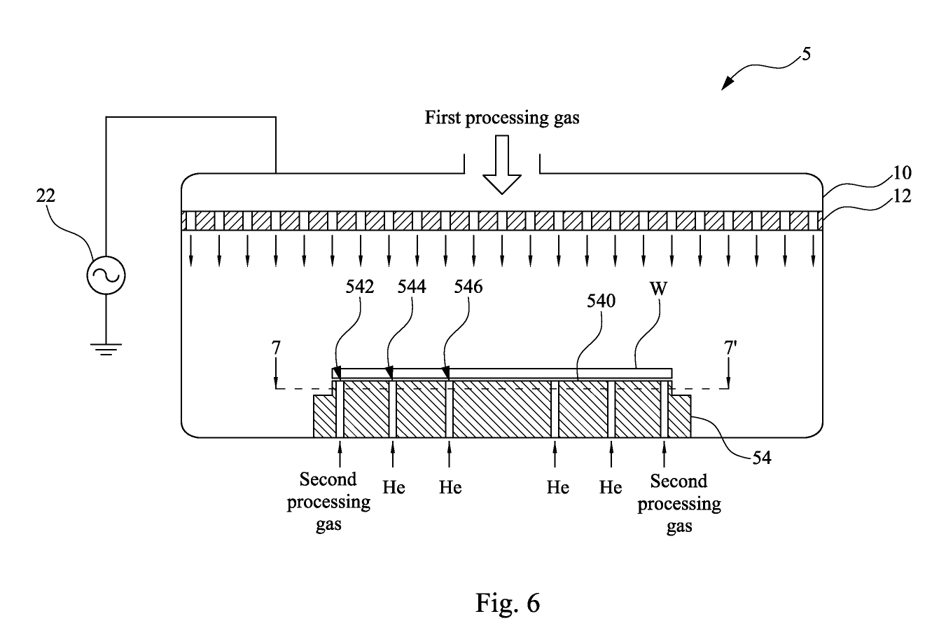

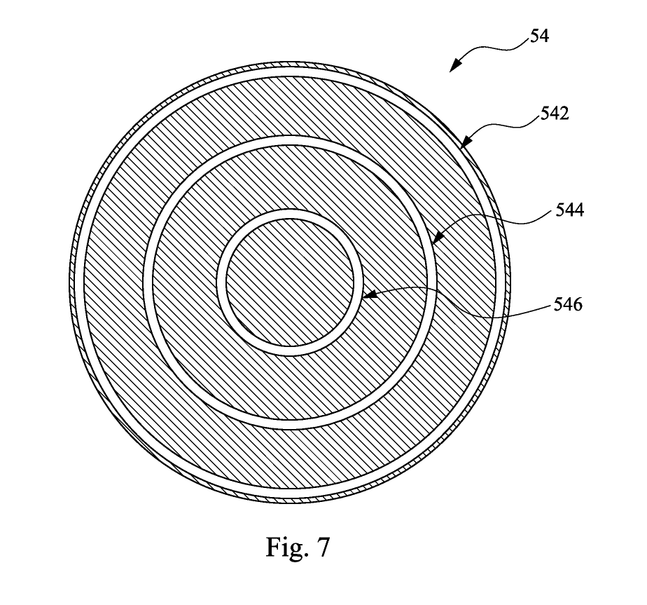

FIG. 6 is a schematic diagram of an etching apparatus 5 for etching a wafer or substrate W in accordance with some embodiments of the present disclosure. FIG. 7 is a sectional view of an electrostatic chuck 54 along line 7-7′ in FIG. 6.

As shown in FIG. 6, the etching apparatus 5 includes a process reaction chamber 10, a gas distribution plate 12, and the electrostatic chuck 54. The gas distribution plate 12 is located in the process reaction chamber 10, and is for entrance of a first processing gas. A gas source (not shown) supplies the first processing gas to be ionized, to the process reaction chamber 10 via the gas distribution plate 12. The first processing gas flowing from the gas distribution plate 12 is excited by an electric field generating device 22 to generate a plasma. The electrostatic chuck 54 is located in the process reaction chamber 10 and has an adsorption surface 540 for supporting and securing the wafer or substrate W to be etched. That is, the wafer or substrate W is located on the adsorption surface 540 of the electrostatic chuck 54. The electrostatic chuck 54 holds the wafer or substrate W to be etched using the ions in the plasma.

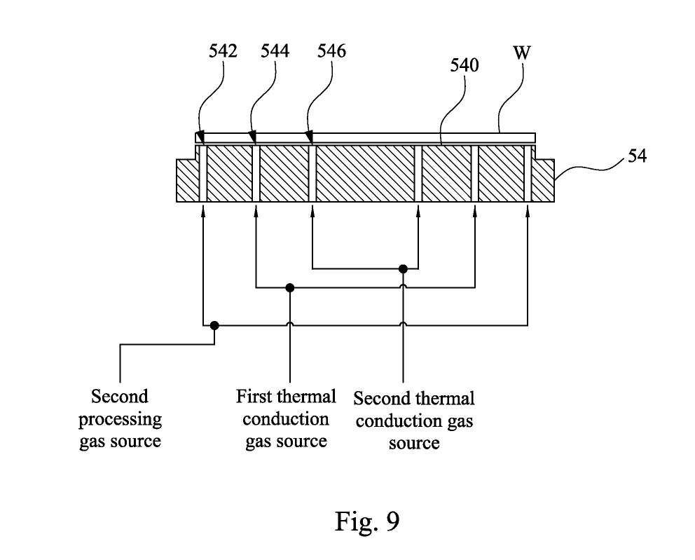

As shown in FIG. 6 and FIG. 7, the electrostatic chuck 54 further has a first annular gas inlet 542 for entrance of a second processing gas from a second processing gas source (as shown in FIG. 9). The first annular gas inlet 542 of the electrostatic chuck 54 is communicated with the adsorption surface 540 of electrostatic chuck 54, and is aligned with the entire edge of the wafer or substrate W. The second processing gas exhausted out from the first annular gas inlet 542 is excited by the electric field generating device 22 to generate another plasma.

Accordingly, besides the plasma excited from the first processing gas can etch the front side (i.e., the upper side) of the wafer or substrate W, the plasma excited from the second processing gas can achieve the purpose of fine tuning the behavior of the etching amount of the edge of the wafer or substrate W, or removing the polymer at the bevel of the wafer or substrate W.

For example, if a photo resist layer deposited at the bevel of the wafer or substrate W needs to be removed, the second processing gas exhausted out from the first annular gas inlet 542 can be oxygen. If an oxide layer deposited at the bevel of the wafer or substrate W needs to be removed, the second processing gas exhausted out from the first annular gas inlet 542 can be a kind of fluorine-based gas.

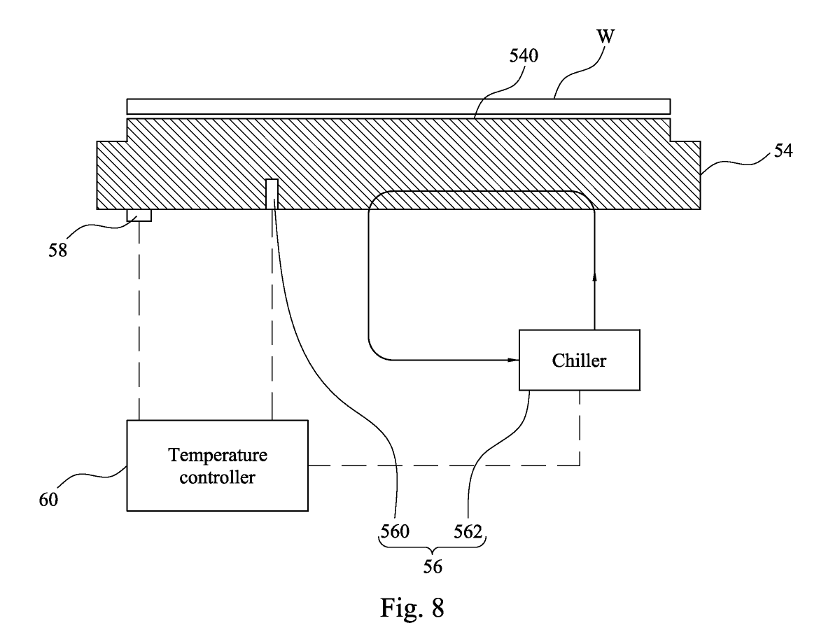

FIG. 8 is a partial schematic diagram of the etching apparatus 5 in FIG. 6 in accordance with some other embodiments of the present disclosure.

As shown in FIG. 8, the etching apparatus 5 further includes a temperature-adjusting module 56. The temperature-adjusting module 56 is thermally connected to the electrostatic chuck 54. The temperature-adjusting module 56 is capable of adjusting the electrostatic chuck 54 to a predetermined temperature. The etching apparatus 5 further includes a temperature sensor 58 and a temperature controller 60. The temperature sensor 58 is thermally connected to the electrostatic chuck 54. The temperature sensor 58 is capable of detecting an actual temperature of the electrostatic chuck 54. The temperature controller 60 is electrically connected to the temperature-adjusting module 56 and the temperature sensor 58. The temperature controller 60 is capable of driving the temperature-adjusting module 56 to adjust the actual temperature of the electrostatic chuck 54 to the predetermined temperature.

In some embodiments of the present application, the temperature-adjusting module 56 includes a heater 560. The heater 560 of the temperature-adjusting module 56 is thermally connected to the electrostatic chuck 54 and electrically connected to the temperature controller 60. The temperature controller 60 is capable of driving the heater 560 to adjust the actual temperature of the electrostatic chuck 54 to the predetermined temperature when the actual temperature is lower than the predetermined temperature.

In some embodiments of the present application, the temperature-adjusting module 56 includes a chiller 562 (as shown in FIG. 8). The chiller 562 of the temperature-adjusting module 56 is thermally connected to the electrostatic chuck 54 and electrically connected to the temperature controller 60. The temperature controller 60 is capable of driving the chiller 562 to adjust the actual temperature of the electrostatic chuck 54 to the predetermined temperature when the actual temperature is higher than the predetermined temperature.

In some embodiments of the present application, the temperature-adjusting module 56 includes the heater 560 and the chiller 562. The temperature controller 60 is capable of driving the heater 560 and the chiller 562 to adjust the actual temperature of the electrostatic chuck 54 to the predetermined temperature.

FIG. 9 is a partial schematic diagram of the etching apparatus 5 in FIG. 6 in accordance with some embodiments of the present disclosure.

As shown in FIG. 7 and FIG. 9, the electrostatic chuck 54 further has a second annular gas inlet 544 for entrance of a thermal conduction gas. The second annular gas inlet 544 of the electrostatic chuck 54 is communicated with the adsorption surface 540 of the electrostatic chuck 54, and is located between the first annular gas inlet 542 and the center of the adsorption surface 540. Hence, the thermal conduction gas exhausted out from the second annular gas inlet 544 of the electrostatic chuck 54 can flow within the gap between the backside (i.e., the lower side) of the wafer or substrate W and the adsorption surface 540 of the electrostatic chuck 54. Thus, the electrostatic chuck 54 can adjust the wafer or substrate W to the predetermined temperature by the thermal conduction gas exhausted out from the second annular gas inlet 544 of the electrostatic chuck 54 in the form of thermal convection.

Furthermore, the electrostatic chuck 54 further has a third annular gas inlet 546 for entrance of the thermal conduction gas. The third annular gas inlet 546 is communicated with the adsorption surface 540 of the electrostatic chuck 54, and is located between the second annular gas inlet 544 and the center of the adsorption surface 540. Similarly, the thermal conduction gas exhausted out from the third annular gas inlet 546 of the electrostatic chuck 54 can also flow within the gap between the backside of the wafer or substrate W and the adsorption surface 540 of the electrostatic chuck 54.

It should be pointed out that in some embodiments of the present disclosure, the second annular gas inlet 544 of the electrostatic chuck 54 is communicated with a first thermal conduction gas source. The thermal conduction gas exhausted out from the second annular gas inlet 544 has a first air pressure. The third annular gas inlet 546 of the electrostatic chuck 54 is communicated with a second thermal conduction gas source. The thermal conduction gas exhausted out from the third annular gas inlet 546 has a second air pressure different from the first air pressure. Hence, the first air pressure of the thermal conduction gas exhausted out from the second annular gas inlet 544 can be selectively adjusted to be larger than or smaller than the second air pressure of the thermal conduction gas exhausted out from the third annular gas inlet 546 as needed, so that the process flexibility of the etching apparatus 5 of the present application can be increased.

In some embodiment of the present application, the thermal conduction gas is an inert gas. The inert gas is a gas that does not undergo chemical reactions under a set of given conditions (i.e., dose not undergo chemical reactions with the first and second processing gases).

In some embodiment of the present application, as shown in FIG. 6, the gas distribution plate 12 and the electrostatic chuck 54 are respectively located at two opposite sides of the process reaction chamber 10, but the application is not limited in this regard.

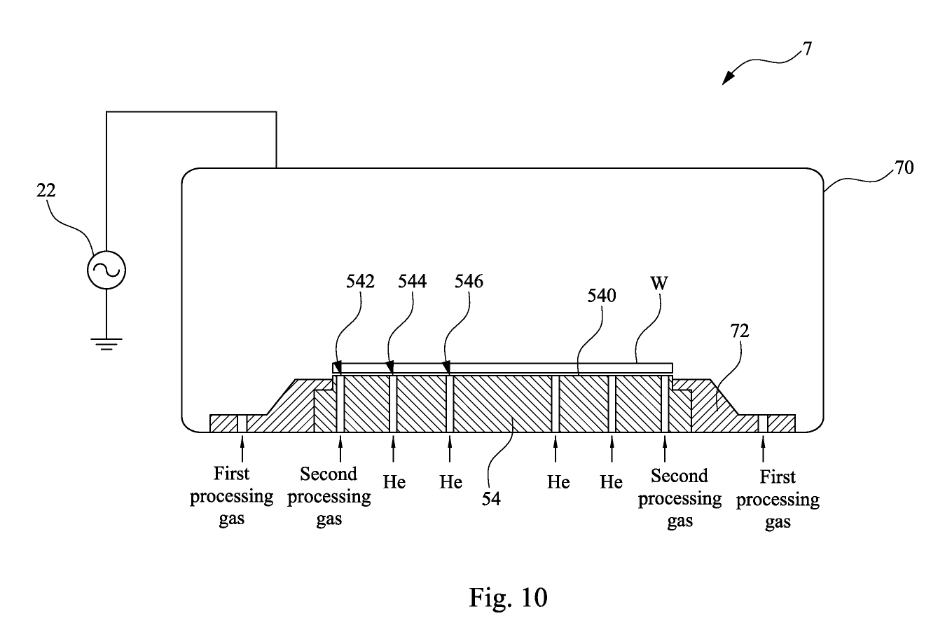

FIG. 10 is a schematic diagram of an etching apparatus 7 for etching a wafer or substrate W in accordance with some other embodiments of the present disclosure.

As shown in FIG. 10, the etching apparatus 5 includes a process reaction chamber 70, a gas distribution plate 12, and the electrostatic chuck 54. It should be pointed out that compared with the embodiment in FIG. 6, the gas distribution plate 72 and the electrostatic chuck 54 of the embodiment in FIG. 10 are located at a side (i.e., the bottom side) of the process reaction chamber 70, and the gas distribution plate 72 is engaged with the peripheral edge of the electrostatic chuck 54.

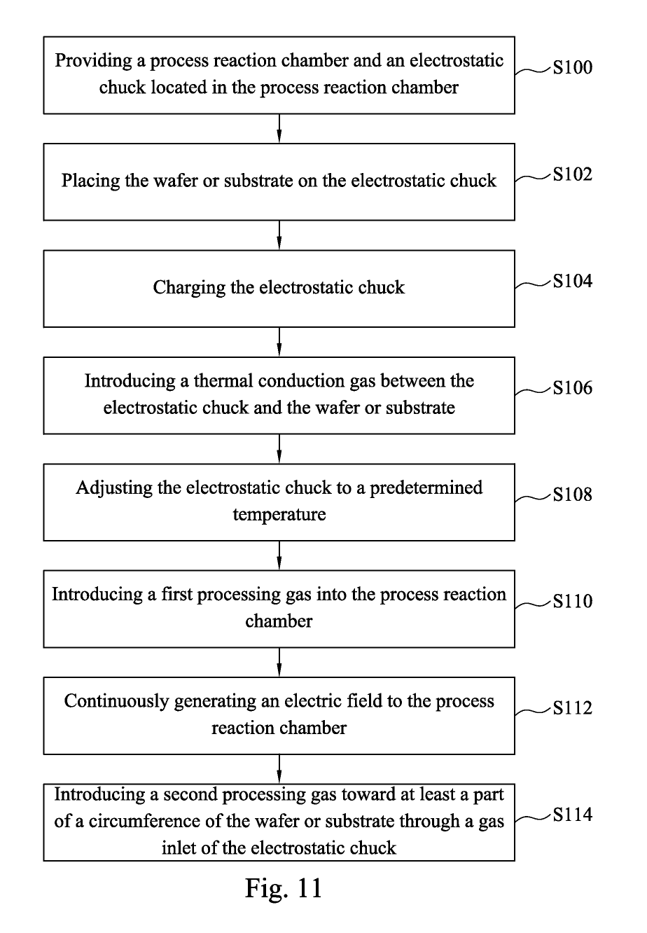

FIG. 11 is a flow chart of an etching method for etching a wafer or substrate in accordance with some embodiments of the present disclosure. The etching method shown in FIG. 11 is for illustrative purpose.

As shown in FIG. 11 with reference to FIG. 1 to FIG. 10, the etching method includes steps S100˜S114 shown below.

S100: providing a process reaction chamber and an electrostatic chuck located in the process reaction chamber.

S102: placing the wafer or substrate on the electrostatic chuck.

S104: charging the electrostatic chuck, so as to adsorb the wafer or substrate on the electrostatic chuck.

S106: introducing a thermal conduction gas between the electrostatic chuck and the wafer or substrate.

S108: adjusting the electrostatic chuck to a predetermined temperature.

S110: introducing a first processing gas into the process reaction chamber.

S112: continuously generating an electric field to the process reaction chamber, so as to excite the first processing gas to generate a first plasma to etch the wafer or substrate.

S114: introducing a second processing gas toward at least a part of a circumference of the wafer or substrate through a gas inlet of the electrostatic chuck, so that the second processing gas is excited by the electric field to generate a second plasma to the part of the edge of the wafer or substrate.

The above illustrations include exemplary steps, but the steps are not necessarily performed in the order shown. Steps may be added, replaced, changed order, and/or eliminated as appropriate, in accordance with the spirit and scope of various embodiments of the present disclosure.

In some embodiments, an etching apparatus is disclosed for etching a wafer or substrate. The etching apparatus includes a process reaction chamber, a gas distribution plate, and an electrostatic chuck. The gas distribution plate is located in the process reaction chamber, and is used for entrance of a main processing gas. The electrostatic chuck is located in the process reaction chamber and has an adsorption surface. The wafer or substrate is located on the adsorption surface. The electrostatic chuck further has a plurality of first gas inlets for entrance of a plurality of auxiliary processing gases. Each of the first gas inlets is communicated with the adsorption surface and aligned with at least a part of the edge of the wafer or substrate. The gas distribution plate and the electrostatic chuck are located at two opposite sides of the process reaction chamber, respectively.

Also disclosed is an etching apparatus for etching a wafer or substrate. The etching apparatus includes a process reaction chamber, a gas distribution plate, and an electrostatic chuck. The gas distribution plate is located in the process reaction chamber, and is used for entrance of a first processing gas. The electrostatic chuck is located in the process reaction chamber and has an adsorption surface. The wafer or substrate is located on the adsorption surface. The electrostatic chuck further has a first annular gas inlet for entrance of a second processing gas. The first gas inlet is communicated with the adsorption surface and aligned with the entire edge of the wafer or substrate.

An etching method is also disclosed for etching a wafer or substrate. The etching method includes steps of: providing a process reaction chamber and an electrostatic chuck located in the process reaction chamber; placing the wafer or substrate on the electrostatic chuck; introducing a first processing gas into the process reaction chamber; continuously generating an electric field to the process reaction chamber, so as to excite the first processing gas to generate a first plasma to etch the wafer or substrate; and introducing a second processing gas toward at least a part of a circumference of the wafer or substrate through a gas inlet of the electrostatic chuck, so that the second processing gas is excited by the electric field to generate a second plasma to the part of the edge of the wafer or substrate.

According to the foregoing recitations of the embodiments of the disclosure, it can be seen that the etching apparatus and method for etching a wafer or substrate integrate the process gas at the edge area of the electrostatic chuck, so as to achieve the purpose of fine tuning the behavior of the etching amount of the edge of the wafer or substrate, or removing the polymer at the bevel of the wafer or substrate. Furthermore, the first air pressure of the thermal conduction gas exhausted out from the second gas inlet(s) can be selectively adjusted to be larger than or smaller than the second air pressure of the thermal conduction gas exhausted out from the third gas inlet(s) as needed, so that the process flexibility of the etching apparatus of the present application can be increased.

As is understood by one of ordinary skill in the art, the foregoing embodiments of the present disclosure are illustrative of the present disclosure rather than limiting of the present disclosure. It is intended to cover various modifications and similar arrangements included within the spirit and scope of the appended claims, the scope of which should be accorded with the broadest interpretation so as to encompass all such modifications and similar structures.

1. An etching apparatus comprising:
a process reaction chamber;
a gas distribution plate disposed in the process reaction chamber for entrance of a main processing gas; and
an electrostatic chuck disposed in the process reaction chamber and having an adsorption surface for supporting and securing a wafer or substrate to be etched, the electrostatic chuck further having a plurality of first gas inlets for entrance of a plurality of auxiliary processing gases, wherein each of the first gas inlets is communicated with the adsorption surface and aligned with at least a part of a circumference of the wafer or substrate, and the gas distribution plate and the electrostatic chuck are located at two opposite sides of the process reaction chamber, respectively.

2. The etching apparatus of claim 1, further comprising:
a plurality of auxiliary processing gas generators communicated with the first gas inlets, the auxiliary processing gas generators respectively generating the auxiliary processing gases;
a gas flow controller communicated with the auxiliary processing gas generators and the first gas inlets, the gas flow controller selectively allowing one of the auxiliary processing gases to exhaust out of the first gas inlets.

3. The etching apparatus of claim 1, further comprising:
a temperature sensor thermally connected to the electrostatic chuck, the temperature sensor detecting an actual temperature of the electrostatic chuck;
a heater thermally connected to the electrostatic chuck;
a chiller thermally connected to the electrostatic chuck; and
a temperature controller electrically connected to the temperature sensor, the heater, and the chiller, the temperature controller driving the heater and the chiller to adjust the actual temperature to a predetermined temperature.

4. The etching apparatus of claim 1, wherein the electrostatic chuck further has a plurality of second gas inlets for entrance of a thermal conduction gas, the distance between any of the second gas inlets and the center of the adsorption surface is smaller than the distance between any of the first gas inlets and the center of the adsorption surface.

5. The etching apparatus of claim 4, wherein the electrostatic chuck further has a plurality of third gas inlets for entrance of the thermal conduction gas, the distance between any of the third gas inlets and the center of the adsorption surface is smaller than the distance between any of the second gas inlets and the center of the adsorption surface.

6. The etching apparatus of claim 5, further comprising:
a thermal conduction gas generator communicated with the second gas inlets and the third gas inlets, the thermal conduction gas generator generating the thermal conduction gas;
a first gas pressure controller communicated with the thermal conduction gas generator and the second gas inlets, the first gas pressure controller adjusting the thermal conduction gas exhausted out from the second gas inlets to a first air pressure; and
a second gas pressure controller communicated with the thermal conduction gas generator and the third gas inlets, the second gas pressure controller adjusting the thermal conduction gas exhausted out from the third gas inlets to a second air pressure different from the first air pressure.

7. The etching apparatus of claim 4, wherein the thermal conduction gas comprises Helium.

8-20. (canceled)

21. The etching apparatus of claim 1, wherein one of the auxiliary processing gases is oxygen.

22. The etching apparatus of claim 1, wherein one of the auxiliary processing gases is a fluorine-based gas.

23. The etching apparatus of claim 3, wherein the electrostatic chuck further has a bottom surface facing away from the wafer or substrate, and the temperature sensor is disposed on the bottom surface.

24. The etching apparatus of claim 3, wherein the electrostatic chuck further has a bottom surface facing away from the wafer or substrate, and the heater is embedded into the electrostatic chuck from the bottom surface.

25. The etching apparatus of claim 4, wherein the thermal conduction gas comprises an inert gas.

26. The etching apparatus of claim 5, wherein the number of the first gas inlets, the number of the second gas inlets, and the number of the third gas inlets are the same.

27. The etching apparatus of claim 26, wherein each of the second gas inlets is located between the corresponding first gas inlet and the corresponding third gas inlet.

28. The etching apparatus of claim 27, wherein each of the second gas inlets and the corresponding first and third gas inlets are arranged in a line.

29. The etching apparatus of claim 5, wherein a cross-section of each of the first gas inlets, the second gas inlets, and the third gas inlets is substantially round shaped.

30. The etching apparatus of claim 6, wherein the first air pressure is larger than the second air pressure.

31. The etching apparatus of claim 6, wherein the first air pressure is smaller than the second air pressure.

32. The etching apparatus of claim 1, further comprising an electric field generating device for exciting the main processing gas to generate a plasma.

33. The etching apparatus of claim 32, wherein the electric field generating device is located outside the process reaction chamber.
